(19) United States
(12) Patent Application Publication
(10) Pub. No.: US 2025/0391360 A1
(43) Pub. Date: Dec. 25, 2025

(54) DISPLAY DEVICE AND ELECTRONIC DEVICE

(71) Applicant: Samsung Display Co., LTD., Yongin-si (KR)

(72) Inventors: Dong Hee SHIN, Yongin-si (KR); Sun Kwun SON, Yongin-si (KR)

(21) Appl. No.: 19/171,413

(22) Filed: Apr. 7, 2025

(30) Foreign Application Priority Data
Jun. 19, 2024 (KR) 10-2024-0079772

(51) Int. Cl. G09G 3/3233; G06V 40/13; G09G 3/32; H10F 39/00

(52) U.S. Cl. CPC G09G 3/3233; G06V 40/1318; H10F 39/802; H10F 39/811; G09G 3/32; G09G 2300/0819; G09G 2300/0842; G09G 2300/0861; G09G 2310/08; G09G 2360/14

(57) ABSTRACT

A display device of the present disclosure includes a circuit layer including pixel circuits and sensor circuits; and an element layer which is positioned on the circuit layer and includes light-emitting elements connected to the pixel circuits and light-receiving elements connected to the sensor circuits, wherein the light-receiving elements include a first light-receiving element, a second light-receiving element, a third light-receiving element, and a fourth light-receiving element, the sensor circuits include: a first sensor circuit connected to the first light-receiving element; a second sensor circuit connected to the second light-receiving element; and a third sensor circuit connected to the third light-receiving element and the fourth light-receiving element, and a planar distance between the first light-receiving element and the third light-receiving element is substantially the same as a planar distance between the second light-receiving element and the fourth light-receiving element.

This application claims priority to Korean patent application number 10-2024-0079772, filed on Jun. 19, 2024, and all the benefits accruing therefrom under 35 U.S.C. § 119, the content of which in its entirety is herein incorporated by reference.

### BACKGROUND OF THE INVENTION

### 1. Field

Embodiments of the present disclosure relate to a display device and an electronic device.

### 2. Description of the Related Art

With development of information technology, the importance of display devices, which are the connecting medium between users and information, is being highlighted. In response, the use of display devices such as liquid crystal display devices and organic light emitting display devices is increasing.

The display device uses pixels to display an image. In addition, the display device may use a plurality of optical sensors to sense a user's fingerprint and perform user authentication functions. Recently, in-cell display panels are being manufactured in which pixels and optical sensors are formed in the same process.

### SUMMARY OF THE INVENTION

A technical object to be achieved is to provide a display device and an electronic device capable of satisfying resolution conditions of pixels and optical sensors and at the same time generating sensing information of uniform quality.

A display device according to an embodiment of the present disclosure includes: a circuit layer including pixel circuits and sensor circuits; and an element layer which is positioned on the circuit layer and includes light-emitting elements connected to the pixel circuits and light-receiving elements connected to the sensor circuits, wherein the light-receiving elements include a first light-receiving element, a second light-receiving element, a third light-receiving element, and a fourth light-receiving element, the sensor circuits include: a first sensor circuit connected to the first light-receiving element; a second sensor circuit connected to the second light-receiving element; and a third sensor circuit connected to the third light-receiving element and the fourth light-receiving element, and a planar distance between the first light-receiving element and the third light-receiving element is substantially the same as a planar distance between the second light-receiving element and the fourth light-receiving element.

The first sensor circuit and the second sensor circuit may be commonly connected to a first scan line.

A second scan line connected to the third sensor circuit may be the next scan line of the first scan line.

The light-receiving elements may further include a fifth light-receiving element and a sixth light-receiving element, the sensor circuits may include: a fourth sensor circuit connected to the fifth light-receiving element; and a fifth sensor circuit connected to the sixth light-receiving element, and a planar distance between the fifth light-receiving element and the third light-receiving element may be substantially the same as a planar distance between the sixth light-receiving element and the fourth light-receiving element.

The first sensor circuit and the second sensor circuit may be commonly connected to a first scan line, a second scan line connected to the third sensor circuit may be the next scan line of the first scan line, and a third scan line to which the fourth sensor circuit and the fifth sensor circuit are commonly connected may be the next scan line of the second scan line.

The light-emitting elements may include first light-emitting elements configured to emit light of a first color, second light-emitting elements configured to emit light of a second color, and third light-emitting elements configured to emit light of a third color, during a sensing period, the first light-emitting elements and the third light-emitting elements in a sensing area may be in a non-light-emitting state, and the second light-emitting elements in the sensing area may be in a light-emitting state, sensing information may include first sensing information for a position of the first light-receiving element, second sensing information for a position of the second light-receiving element, third sensing information for a position of the third light-receiving element, and fourth sensing information for a position of the fourth light-receiving element, and the first sensing information may correspond to a level of a first sensing signal output from the first sensor circuit, the second sensing information may correspond to a level of a second sensing signal output from the second sensor circuit, the third sensing information may correspond to a half level of a third sensing signal output from the third sensor circuit, and the fourth sensing information may correspond to a half-level of the third sensing signal.

The light-emitting elements may include first light-emitting elements configured to emit light of a first color, second light-emitting elements configured to emit light of a second color, and third-emitting elements configured to emit light of a third color, and, during a first sensing period, the first light-emitting elements and the third light-emitting elements in a sensing area may be in a non-light-emitting state, some of the second light-emitting elements adjacent to the first light-receiving element, the second light-receiving element, and the third light-receiving element may be in a light-emitting state, and at least one of the second light-emitting elements adjacent to the fourth light-receiving element may be in the non-light-emitting state.

During a second sensing period, the first light-emitting elements and the third light-emitting elements in the sensing area may be in the non-light-emitting state, some of the second light-emitting elements adjacent to the first light-receiving element, the second light-receiving element, and the fourth light-receiving element may be in the light-emitting state, and at least one of the second light-emitting elements adjacent to the third light-receiving element may be in the non-light-emitting state.

The sensing information may include first sensing information for a position of the first light-receiving element, second sensing information for a position of the second light-receiving element, third sensing information for a position of the third light-receiving element, and fourth sensing information for a position of the fourth light-receiving element, the first sensing information may correspond to an average level of a first sensing signal output during the first sensing period and a first sensing signal output during the second sensing period from the first sensor circuit, the second sensing information may correspond to an average level of a second sensing signal output during the first sensing period and a second sensing signal output during the second sensing period from the second sensor circuit, the third sensing information may correspond to a level of a third sensing signal output during the first sensing period from the third sensor circuit, and the fourth sensing information may correspond to a level of a third sensing signal output during the second sensing period from the third sensor circuit.

A display device according to an embodiment of the present disclosure includes: a circuit layer including pixel circuits and sensor circuits; and an element layer which is positioned on the circuit layer and includes light-emitting elements connected to the pixel circuits and light-receiving elements connected to the sensor circuits, wherein the light-receiving elements include a first light-receiving element, a second light-receiving element, a third light-receiving element, and a fourth light-receiving element, the sensor circuits include: a first sensor circuit connected to the first light-receiving element; a second sensor circuit connected to the second light-receiving element; and a third sensor circuit connected to the third light-receiving element and the fourth light-receiving element, and a planar distance between the first light-receiving element and the third light-receiving element is substantially the same as a planar distance between the second light-receiving element and the third light-receiving element.

A planar distance between the first light-receiving element and the fourth light-receiving element may be substantially the same as a planar distance between the second light-receiving element and the fourth light-receiving element.

The light-receiving elements may further include a fifth light-receiving element and a sixth light-receiving element, the sensor circuits may include: a fourth sensor circuit connected to the fifth light-receiving element; and a fifth sensor circuit connected to the sixth light-receiving element, and a planar distance between the fifth light-receiving element and the fourth light-receiving element may be substantially the same as a planar distance of the sixth light-receiving element and the fourth light-receiving element.

The first sensor circuit and the second sensor circuit may be commonly connected to a first scan line, a second scan line connected to the third sensor circuit may be the next scan line of the first scan line, and a third scan line to which the fourth sensor circuit and the fifth sensor circuit are commonly connected may be the next scan line of the second scan line.

A planar distance of the first light-receiving element and the fourth light-receiving element may be different from a planar distance between the second light-receiving element and the fourth light-receiving element.

A length of a conductor connecting the third light-receiving element and the third sensor circuit may be substantially the same as a length of a conductor connecting the fourth light-receiving element and the third sensor circuit.

The light-receiving elements may further include a fifth light-receiving element and a sixth light-receiving element, the sensor circuits may include: a fourth sensor circuit connected to the fifth light-receiving element; and a fifth sensor circuit connected to the sixth light-receiving element, and a planar distance between the fifth light-receiving element and the fourth light-receiving element may be substantially the same as a planar distance between the sixth light-receiving element and the fourth light-receiving element.

The second light-receiving element may be located in a first direction from the first light-receiving element, and the fifth light-receiving element may be located in a second direction perpendicular to the first direction from the second light-receiving element.

A display device according to an embodiment of the present disclosure includes: a circuit layer including pixel circuits and sensor circuits; and an element layer which is positioned on the circuit layer and includes light-emitting elements connected to the pixel circuits and light-receiving elements connected to the sensor circuits, wherein the light-receiving elements include a first light-receiving element, a second light-receiving element, a third light-receiving element, a fourth light-receiving element, a fifth light-receiving element, and a sixth light-receiving element, the sensor circuits include: a first sensor circuit connected to the first light-receiving element; a second sensor circuit connected to the second light-receiving element; a third sensor circuit connected to the third light-receiving element and the fifth light-receiving element; and a fourth sensor circuit connected to the fourth light-receiving element and the sixth light-receiving element, and a planar distance between the first light-receiving element and the third light-receiving element is substantially the same as a planar distance between the second light-receiving element and the fourth light-receiving element.

The second light-receiving element may be located in a first direction from the first light-receiving element, the fourth light-receiving element may be located in the first direction from the third light-receiving element, and the sixth light-receiving element may be located in the first direction from the fifth light-receiving element.

The first sensor circuit and the second sensor circuit may be commonly connected to a first scan line, a second scan line connected to the third sensor circuit may be the next scan line of the first scan line, and the third scan line connected to the fourth sensor circuit may be the next scan line of the second scan line.

An electronic device according to an embodiment of the present disclosure includes: a processor to provide input image data; and a display device to display an image based on the input image data, the display device including: a circuit layer comprising pixel circuits and sensor circuits; and an element layer positioned on the circuit layer and comprising light-emitting elements connected to the pixel circuits and light-receiving elements connected to the sensor circuits. The light-receiving elements include a first light-receiving element, a second light-receiving element, a third light-receiving element, and a fourth light-receiving element. The sensor circuits include: a first sensor circuit connected to the first light-receiving element; a second sensor circuit connected to the second light-receiving element; and a third sensor circuit connected to the third light-receiving element and the fourth light-receiving element. A planar distance between the first light-receiving element and the third light-receiving element is substantially the same as a planar distance between the second light-receiving element and the fourth light-receiving element.

The first sensor circuit and the second sensor circuit may be commonly connected to a first scan line.

A second scan line connected to the third sensor circuit may be a next scan line of the first scan line.

A display device and an electronic device according to the present disclosure is capable of satisfying the resolution conditions of the pixels and optical sensors and at substantially the same time generating sensing information of uniform quality.

### BRIEF DESCRIPTION OF THE DRAWINGS

FIG. 1 is a drawing for illustrating a display device according to an embodiment of the present disclosure.

FIG. 2 is a drawing for illustrating a pixel according to an embodiment of the present disclosure.

FIG. 3 is a drawing for illustrating an optical sensor according to an embodiment of the present disclosure.

FIG. 4 is a drawing for illustrating a driving method of a pixel and an optical sensor according to an embodiment of the present disclosure.

FIG. 5 is a drawing for illustrating a stacked structure of a display panel according to an embodiment of the present disclosure.

FIG. 6 is a plan view for illustrating a circuit layer according to an embodiment of the present disclosure.

FIG. 7 is a plan view for illustrating an element layer according to an embodiment of the present disclosure.

FIG. 8 is a plan view for illustrating an element layer according to another embodiment of the present disclosure.

FIG. 9 is a drawing for illustrating an optical sensor including an auxiliary light-receiving element according to the embodiment of the present disclosure of FIG. 8.

FIG. 10 is a drawing for illustrating a sensing method of the element layer of FIG. 8.

FIGS. 11 and 12 are diagrams for illustrating another sensing method of the element layer of FIG. 8.

FIGS. 13 to 15 are diagrams for illustrating element layers according to other embodiments of the present disclosure.

FIG. 16 is a block diagram illustrating an electronic device according to embodiments of the present disclosure.

FIG. 17 is a drawing for illustrating an example of the electronic device of FIG. 16 implemented as a smartphone.

FIG. 18 is a drawing for illustrating an example of the electronic device of FIG. 16 implemented as a tablet PC.

### DETAILED DESCRIPTION

Hereinafter, referring to the accompanied drawings, various embodiments of the present disclosure are described in detail so that a person skilled in the art to which the present disclosure pertains may easily implement them. The present disclosure may be implemented in a number of different forms and is not limited to embodiments described herein.

In order to clearly explain the present disclosure, parts irrelevant to the description are omitted, and the same reference numerals are used for identical or similar components throughout the specification. Therefore, the reference numerals described previously may be used in other drawings as well.

In addition, the size and thickness of each configuration shown in drawings are arbitrarily represented for ease of explanation, so that the present disclosure is not necessarily limited to what is illustrated. Thicknesses may be exaggerated in order to clearly represent multiple layers and areas in the drawings.

Further, the expression “the same” in the description may mean “substantially the same”. In other words, this expression may indicate that two parts are so identical that a person skilled in the art would be convinced that they are identical. Other expressions may also be expressions from which the word “substantially” is omitted.

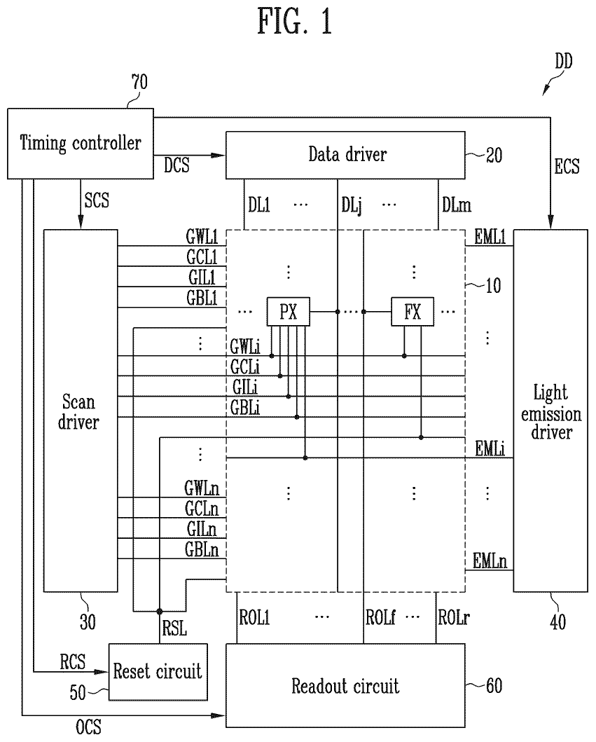

FIG. 1 is a drawing for illustrating a display device according to an embodiment of the present disclosure.

Referring to FIG. 1, a display device (DD) according to an embodiment of the present disclosure may include a display panel 10, a data driver 20, a scan driver 30, a light emission driver 40, a reset circuit 50, a readout circuit 60, and a timing controller 70.

The timing controller 70 may receive gradations and timing signals for each frame period from a processor. The processor may be at least one of a graphics processing unit (GPU), a central processing unit (CPU), an application processor (AP), and the like. Timing signals may include vertical synchronization signals, horizontal synchronization signals, data enable signals, and the like.

Each cycle of the vertical synchronous signal may correspond to each frame period. Each cycle of the horizontal synchronous signal may correspond to each horizontal period. The gradations may be supplied in units of horizontal lines in each horizontal period to correspond to an enable-level pulse of a data-enable signal. The horizontal line may refer to pixels connected to the same first scan line (e.g., a pixel row).

The timing controller 70 may generate a first control signal (SCS), a second control signal (ECS), a third control signal (DCS), a fourth control signal (RCS), and a fifth control signal (OCS) based on the received gradations and timing signals. The first control signal (SCS) may be supplied to the scan driver 30, the second control signal (ECS) may be supplied to the light emission driver 40, the third control signal (DCS) may be supplied to the data driver 20, the fourth control signal (RCS) may be supplied to the reset circuit 50, and the fifth control signal (OCS) may be supplied to the readout circuit 60. The timing controller 70 may rearrange (e.g., render) and correct the gradations and supply them to the data driver 20.

The display panel 10 may include pixels (PXs) connected to data lines (DL1, . . . , DLj, . . . , DLm), scan lines (GWL1, . . . , GWLi, . . . , GWLn, GCL1, . . . , GCLi, . . . , GCLn, GIL1, . . . , GILi, . . . , GILn, GBL1, . . . , GBLi, . . . , GBLn), and light emission lines (EML1, . . . , EMLi, . . . , EMLn). Each pixel (PX) may include a light-emitting element which receives a data voltage from a corresponding data line and emits light with a brightness based on the data voltage. In addition, the display panel 10 may include optical sensors (FXs) which are connected to the first scan lines (GWL1, . . . , GWLi, . . . , GWLn), a reset line (RSL), and readout lines (ROL1, . . . , ROLf, . . . , ROLr). Each optical sensor (FX) may include a light-receiving element and may provide a sensing current generated based on the amount of light received by the light-receiving element to the corresponding readout line. Here, m, n, and r may be integers greater than 1.

The data driver 20 may receive gradations and a third control signal (DCS) from the timing controller 70. For example, the third control signal (DCS) may include a source start signal, a clock signal, and the like. For example, the data driver 20 may sample the gradations while shifting the source start signal based on the clock signal, and apply data voltages corresponding to the sampled gradations to the data lines (DL1 to DLm) per pixel column.

The scan driver 30 may receive the first control signal (SCS) from the timing controller 70. The first control signal (SCS) may include a clock signal, a scan start signal, and the like. The scan driver 30 may supply scan signals to scan lines (GWL1, . . . , GWLi, . . . , GWLn, GCL1, . . . , GCLi, . . . , GCLn, GIL1, . . . , GILi, . . . , GILn, GBL1, . . . , GBLi, . . . , GBLn).

In FIG. 1, an embodiment is illustrated in which the scan lines (GWL1, . . . , GWLi, . . . , GWLn, GCL1, . . . , GCLi, . . . , GCLn, GIL1, . . . , GILi, . . . , GILn, GBL1, . . . , GBLi, . . . , GBLn) are connected to one scan driver 30, but the disclosure is not limited thereto. For example, the scan driver 30 may include a first sub-scan driver connected to the first scan lines (GWL1, . . . , GWLi, . . . , GWLn), a second sub-scan driver connected to the second scan lines (GCL1, . . . , GCLi, . . . , GCLn), a third sub-scan driver connected to the third scan lines (GIL1, . . . , GILi, . . . , GILn), and a fourth sub-scan driver connected to the fourth scan lines (GBL1, . . . , GBLi, . . . , GBLn). In another example, the scan driver 30 may be configured to include a first sub-scan driver connected to the scan lines (GWL1, . . . , GWLi, . . . , GWLn, GBL1, . . . , GBLi, . . . , GBLn) and a second sub-scan driver connected to scan lines (GCL1, . . . , GCLi, . . . , GCLn, GIL1, . . . , GILi, . . . , GILn).

The scan driver 30 or each sub-scan driver may sequentially supply the scan signals with turn-on level pulses to the corresponding scan lines. The scan driver 30 or each sub-scan driver may include scan stages configured in the form of a shift register. The scan driver 30 or each sub-scanning driver may generate scan signals by sequentially transmitting the scan start signal in the form of a pulse of a turn-on level to the next scan stage according to control of the clock signal.

The light emission driver 40 may receive the second control signal (ECS) from the timing controller 70. The second control signal (ECS) may include a clock signal, a light emission stop signal, and the like. The light emission driver 40 may supply light emission signals to the light emission lines (EML1 to EMLn) in response to the second control signal (ECS).

The light emission driver 40 may sequentially supply light emission signals with turn-off-level pulses to the light emission lines (EML1 to EMLn). The light emission driver 40 may include light emission stages configured in the form of shift registers. The light emission driver 40 may generate light emission signals by sequentially transmitting the light emission stop signal in the form of a pulse of a turn-off level to the next light emission stage according to control of the clock signal.

In FIG. 1, an embodiment is illustrated in which the scan driver 30 and the light emission driver 40 are provided as separate configurations, but the disclosure is not limited thereto. For example, the scanning drive 30 and the light emission driver 40 may be integrated into one driving circuit, one module, or the like.

The reset circuit 50 may receive the fourth control signal (RCS) from the timing controller 70. The reset circuit 50 may apply a reset signal to the reset line (RSL) in response to the fourth control signal (RCS). The reset line (RSL) may be commonly connected to all the optical sensors (FXs) of the display panel 10. In other words, a common reset signal may be transmitted to all the optical sensors (FXs). On the other hand, in another embodiment, the reset circuit 50 may be connected to a plurality of optical sensors (FXs) through a plurality of reset lines. In this case, a plurality of different reset signals may be transmitted to different optical sensors (FXs).

For sensing, at least some of the pixels (PXs) located in a selected area may emit light in a sensing pattern. The selected area may be an area which is obscured by a user's finger touch. The sensing pattern may be a single color pattern (e.g., a red pattern or a green pattern). In addition, the optical sensors (FXs) may generate sensing signals corresponding to the amount of light received. Pixels (PXs) located outside the selected area may continue to display an existing image. The sensing pattern of the pixels (PXs) located in the selected area obscured by the finger cannot be seen by the user, so the user can continue to enjoy the existing video.

The readout circuit 60 may receive the fifth control signal (OCS) from the timing controller 70. The readout circuit 60 may provide sensing information based on sensing signals received from the readout lines (ROLI to ROLr) in response to the fifth control signal (OCS). The sensing information may be configured in various ways according to modes of the display device (DD). For example, the sensing information may be fingerprint image information, PhotoPlethysmoGraphy (PPG) information, illuminance information, and the like.

The processor or the timing controller 70 may perform a user authentication function using the sensing information provided from the readout circuit 60.

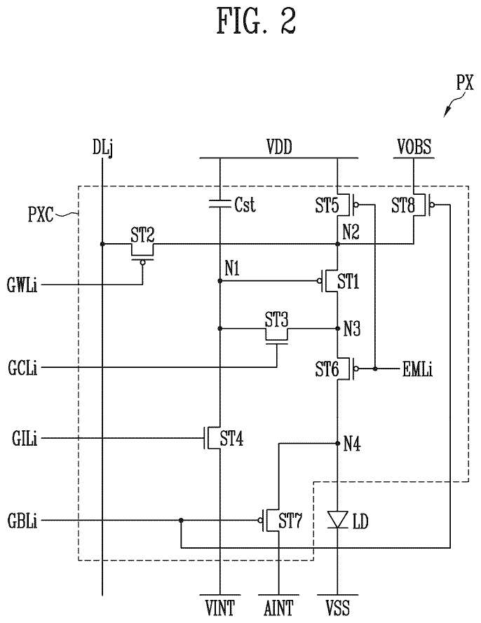

FIG. 2 is a drawing for illustrating a pixel according to an embodiment of the present disclosure.

In FIG. 2, a pixel (PX) placed in the i-th pixel row and the j-th pixel column among a plurality of pixels (PXs) is illustrated as an example. A pixel row may refer to pixels connected to a same first scan line, and a pixel column may refer to pixels connected to a same data line. Here, i is an integer greater than or equal to 1 and less than or equal to n, and j is an integer greater than or equal to 1 and less than or equal to m.

Referring to FIG. 2, the pixel (PX) may include a pixel circuit (PXC) and a light-emitting element (LD). The pixel circuit (PXC) may include pixel transistors (ST1 to ST8) and a storage capacitor (Cst).

For the first pixel transistor (ST1, driving transistor), a gate electrode of may be connected to a first node (N1), a first electrode may be connected to a second node (N2), and a third electrode may be connected to a third node (N3). The first pixel transistor (ST1) may control driving current flowing from a first power supply voltage (VDD) to a second power supply voltage (VSS) through the light-emitting element (LD) in response to the voltage of the first node (N1).

For the second pixel transistor (ST2, switching transistor), a first electrode may connected to the data line (DLj), a second electrode may be connected to the second node (N2), and a gate electrode may be connected to the first scan line (GWLi). The second pixel transistor (ST2) may be turned on when a turn-on level first scan signal is supplied to the first scan line (GWLi) to electrically connect the data line (DLj) to the second node (N2).

For the third pixel transistor (ST3, diode-connected transistor), a first electrode may be connected to the first node (N1), a second electrode may be connected to the third node (N3), and a gate electrode may be connected to the second scan line (GCLi). The third pixel transistor (ST3) may be turned on when a turn-on level second scan signal is supplied to the second scan line (GCLi) to electrically connect the gate electrode of the first pixel transistor (ST1) to the second electrode. In other words, when the third pixel transistor (ST3) is turned on, the first pixel transistor (ST1) may be connected in the form of a diode.

For the fourth pixel transistor (ST4, gate initialization transistor), a first electrode may be connected to the first node N1, a second electrode may be connected to a first initialization voltage line to which a first initialization voltage (VINT) is applied, and a gate electrode may be connected to the third scan line (GILi). The fourth pixel transistor (ST4) may be turned on when a turn-on level third scan signal is supplied to the third scan line (GILi) to supply the first initialization voltage (VINT) to the first node (N1).

For the fifth pixel transistor (ST5, first light-emitting transistor), a first electrode may be connected to a first power line to which the first power supply voltage (VDD) is applied, a second electrode may be connected to the second node (N2), and a gate electrode may be connected to a light emission line (EMLi). The fifth pixel transistor (ST5) may be turned off when a turn-off level light emission signal is supplied to the light emission line (EMLi), and may be turned on otherwise.

For the sixth pixel transistor (ST6, second light-emitting transistor), a first electrode may be connected to the third node (N3), a second electrode may be connected to a fourth node (N4), and a gate electrode may be connected to the light emission line (EMLi). The sixth-pixel transistor (ST6) may be turned off when a turn-off level of light emission signal is supplied to the light emission line (EMLi), and may be turned on otherwise. The pixel (PX) may emit light in response to the light emission signal received from the light emission line (EMLi). In other words, light emitting timing of the pixel (PX) may be determined in response to the light emission signal received from the light emission line (EMLi).

For the seventh-pixel transistor (ST7, anode initialization transistor), a first electrode may be connected to the fourth node (N4), a second electrode may be connected to a second initialization voltage line to which a second initialization voltage (AINT) is applied, and a gate electrode may be connected to the fourth scan line (GBLi). The seventh-pixel transistor (ST7) may be turned on when a turn-on level fourth scan signal is supplied to the fourth scan line (GBLi) to supply the second initialization voltage (AINT) to the fourth node (N4). For example, the i-th fourth scan line (GBLi) may be the same as the i-th first scan line (GWLi).

For the eighth pixel transistor (ST8, bias transistor), a first electrode may receive a bias voltage (VOBS), a second electrode is connected to the second node (N2), and a gate electrode may be connected to the fourth scan line (GBLi). The eighth pixel transistor (ST8) may be turned on when the turn-on level fourth scan signal is supplied to the fourth scan line (GBLi) to supply the bias voltage (VOBS) to the second node (N2).

Among the pixel transistors (STI to ST8), some of the transistors (ST1, ST2, ST5, ST6, ST7, ST8) may be each P-type transistors, and some other transistors (ST3, ST4) may be each N-type transistors, but the disclosures are not limited thereto. For example, each of the pixel transistors (ST1 to ST8) may be either a P-type transistor or an N-type transistor.

The P-type transistors may be polysilicon semiconductor transistors. The polysilicon semiconductor transistor may include a polysilicon semiconductor in a channel of a semiconductor layer. For example, the polysilicon semiconductor transistor may be a low temperature poly-silicon (LTPS) thin-film transistor. The polysilicon semiconductor transistor has high electron mobility and thus fast operating characteristics.

The N-type transistors may be oxide semiconductor transistors. The oxide semiconductor transistor may include an oxide semiconductor in a channel of a semiconductor layer. For example, the oxide semiconductor transistor may be a low temperature polycrystalline oxide (LTPO) thin-film transistor. The oxide semiconductor transistor has lower charge mobility compared to polysilicon semiconductor transistor. Therefore, the oxide semiconductor transistors have less leakage current in the turn-off state than polysilicon semiconductor transistors. These descriptions are omitted hereinafter.

For the storage capacitor (Cst), a first electrode of may be connected to the first power line to which the first power supply voltage (VDD) is applied, and a second electrode may be connected to the first node (N1).

For the light-emitting element (LD), an anode electrode may be connected to the fourth node (N4), and a cathode electrode may be connected to a second power line to which the second power supply voltage (VSS) is applied. The light-emitting device (LD) may be a light-emitting diode. The light-emitting device (LD) may include organic light emitting diodes, inorganic light emitting diodes, and quantum dot/well light emitting diodes. The light-emitting device (LD) may emit light of any of a first color, a second color, and a third color. In addition, in the present embodiment, only one light-emitting element (LD) is provided in each pixel, but in other embodiments, a plurality of light-emitting elements may be provided in each pixel. Here, the plurality of light-emitting elements may be connected in series, parallel, series-parallel, etc.

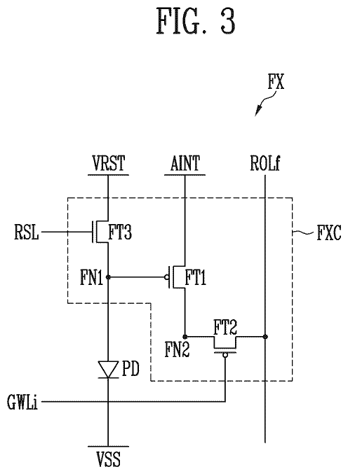

FIG. 3 is a drawing for illustrating an optical sensor according to an embodiment of the present disclosure.

Referring to FIG. 3, an optical sensor (FX) may include a sensor circuit (FXC) and a light-receiving element (PD). The sensor circuit (FXC) may include sensing transistors (FT1 to FT3).

The sensor circuit (FXC) may be connected to an anode electrode of the light-receiving element (PD) at a first node (FN1).

For the first sensing transistor (FT1, amplifying transistor), a first electrode may be connected to a second initialization line to which the second initialization voltage (AINT) is applied, a second electrode may be connected to a second node (FN2), and a gate electrode may be connected to the first node (FN1). The first sensing transistor (FT1) may control sensing current flowing to the first sensing transistor (FT1) in response to the voltage of the first node (FN1). The sensing current may be supplied to the readout line (ROLf) as a sensing signal via a second sensing transistor (FT2). The first node (FN1) may be named a sensing node.

For the second sensing transistor (FT2, output transistor), a first electrode may be connected to the second node (FN2), a second electrode may be connected to the readout line (ROLf), and the gate electrode may be connected to the first scan line (GWLi). In other words, the gate electrode of the second sensing transistor (FT2) and the gate electrode of the second pixel transistor (ST2) may be connected to the same scan line, i.e., the first scan line (GWLi). The second sensing transistor (FT2) may be turned on when a turn-on level first scan signal is supplied to the first scan line (GWLi) to electrically connect the second electrode of the first sensing transistor (FT1) to the readout line (ROLf).

For the third sensing transistor (FT3, reset transistor), a first electrode may be connected to a reset voltage line to which a reset voltage (VRST) is applied, a second electrode may be connected to the first node (FN1), and a gate electrode may be connected to the reset line (RSL). The optical sensor (FX) may reset the voltage of the sensing node (=first node (FN1)) in response to the reset signal received from the reset line (RSL). The third sensing transistor (FT3) may be turned on when a turn-on level reset signal is supplied to the reset line (RSL) and supply the reset voltage (VRST) to the first node (FN1). The gate electrode of the first node (FN1), i.e. the first sensing transistor (FT1), may be reset by the reset voltage (VRST). The reset voltage (VRST) may be set to be less than the second power supply voltage (VSS).

Among the sensing transistors (FT1 to FT3), some transistors (FT1, FT2) may be each P-type transistors, and some other transistors (FT3) may be N-type transistors, but the disclosures are not limited thereto. For example, each of the sensing transistors (FT1 to FT3) may be either a P-type transistor or an N-type transistor.

A first electrode (or anode electrode) of the light-receiving element (PD) may be connected to the first node (FN1), and a second electrode (or cathode electrode) of the light-receiving element (PD) may be connected to the second power line to which the second power supply voltage (VSS) is applied. The light-receiving element (PD) may be a photo diode. However, in another embodiment, the light-receiving element (PD) may include a photo transistor. When the light-receiving element (PD) receives light, electrons are excited, allowing a reverse current to flow from the cathode electrode to the anode electrode. Thus, if the light-receiving element (PD) is exposed to light, the voltage of the first node (FN1) may gradually increase after the time of reset. As the light receiving time becomes longer or the amount of light received increases, the amount of voltage increase of the first node (FN1) after the time of reset may increase. Therefore, according to the light receiving time and the amount of light received, the magnitude of the sensing current flowing through the readout line (ROLf) may vary.

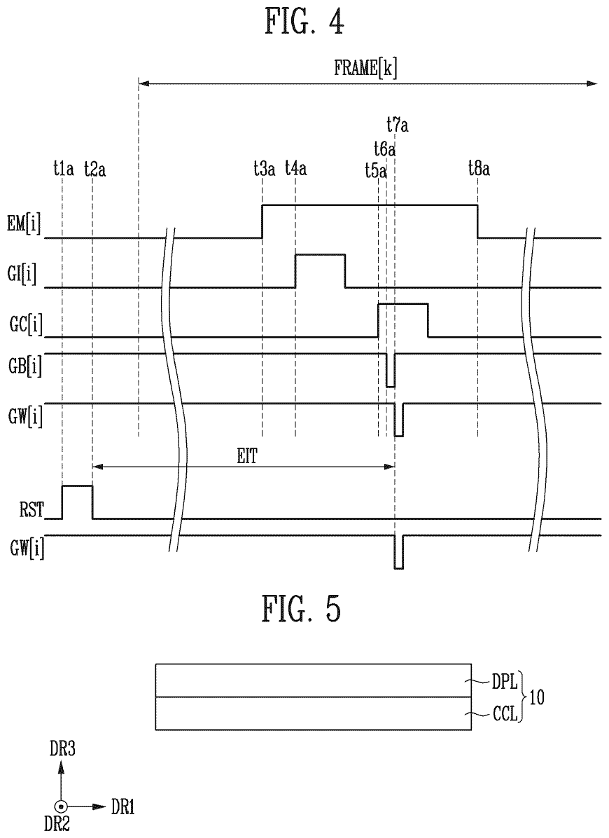

FIG. 4 is a drawing for illustrating a driving method of a pixel and an optical sensor according to an embodiment of the present disclosure.

FIG. 4 illustrates a process in which the pixel (PX) of FIG. 2 and the optical sensor (FX) of FIG. 3 operate in an arbitrary k-th frame period (FRAME[k]).

First, during the period (t1a to t2a) prior to the k-th frame period (FRAME[k]), a turn-on level reset signal (RST) may be applied to the reset line (RSL). Therefore, the first node (FN1) of the optical sensor (FX) may be reset by the reset voltage (VRST). After the time point (t2a), the voltage of the first node (FN1) gradually rises, according to the length of a light receiving period (EIT) and the amount of light received.

At the point (t3a), a turn-off level light emission signal (EM[i]) may be supplied to the light emission line (EMLi). Accordingly, the fifth pixel transistor (ST5) and the sixth pixel transistor (ST6) may be turned off, and the light-emitting element (LD) is prevented from emitting light.

At the time point (t4a), a turn-on level third scan signal (GI[i]) is supplied to the third scan line (GILi). Accordingly, the fourth pixel transistor (ST4) is turned on, and the first node (N1) is initialized to the first initialization voltage (VINT).

At the time point (t5a), a turn-on level second scan signal (GC[i]) is supplied to the second scan line (GCLi). Accordingly, the third pixel transistor (ST3) is turned on, and the first pixel transistor (ST1) is diode-connected.

At the time point (t6a), a turn-on level fourth scan signal (GB[i]) is supplied to the fourth scan line (GBLi). Accordingly, the seventh pixel transistor (ST7) is turned on, and the fourth node (N4) is initialized to the second initialization voltage (AINT). The second initialization voltage (AINT) may be set to a voltage equal to or lower than the second power supply voltage (VSS), which can advantageously facilitate low-grayscale expression of the light-emitting element (LD).

In addition, the eighth pixel transistor (ST8) is turned on, and the second node (N2) is initialized to the bias voltage (VOBS).

At the time point (t7a), a turn-on level first scan signal (GW[i]) is fed to the first scan line (GWLi). Accordingly, the second pixel transistor (ST2) is turned on and the data voltage is applied to the second node (N2). At this time, the first node (N1) is in a state where the first initialization voltage (VINT) is applied, and the first initialization voltage (VINT) may be a voltage sufficiently smaller than the data voltages. Therefore, the first pixel transistor (ST1) may be turned on, and a corrected data voltage in which a threshold voltage reduction is reflected in the data voltage may be applied to the first node (N1). The storage capacitor (Cst) maintains a voltage that corresponds to a difference between the first power supply voltage (VDD) and a compensation data voltage. This period may be called a threshold voltage compensation period or a data writing period.

In addition, at the time point (t7a), the second sensing transistor (FT2) is turn-on by the turn-on level first scan signal (GW[I]). Therefore, a sensing current (e.g., sensing signal) corresponding to the light receiving period (EIT) and the amount of light received may flow to the readout line (ROLf).

At the time point (18a), the turn-on level light emission signal (EM[i]) is supplied to the light emission line (EMLi). Accordingly, the fifth pixel transistor (ST5) and the sixth pixel transistor (ST6) are turned on, and the light-emitting element (LD) becomes capable of emitting light.

At this time, a driving current path is formed which connects the first power line, the fifth pixel transistor (ST5), the first pixel transistor (ST1), the sixth pixel transistor (ST6), the light-emitting element (LD), and the second power line. Depending on the voltage maintained in the storage capacitor (Cst), the amount of driving current flowing to the first and second electrodes of the first pixel transistor (ST1) is regulated. The light-emitting element (LD) emits light with a brightness which corresponds to the amount of driving current. The light-emitting element (LD) may emit light until the turn-off level light emission signal (EM[i]) is applied to the light emission line (EMLi).

FIG. 5 is a drawing for illustrating a stacked structure of a display panel according to an embodiment of the present disclosure.

Referring to FIG. 5, the display panel 10 according to an embodiment of the present disclosure may include a circuit layer (CCL) and an element layer (DPL).

The circuit layer (CCL) and the element layer (DPL) each may have a flat plate shape extending in a first direction (DR1) and a second direction (DR2), respectively. The element layer (DPL) may be located in a third direction (DR3) from the circuit layer (CCL). The first direction (DR1), the second direction (DR2), and the third direction (DR3) may be perpendicular to each other.

The circuit layer (CCL) may include pixel circuits (PXCs) and sensor circuits (FXCs) (see FIGS. 2 and 3). The element layer (DPL) may be located on the circuit layer (CCL). The element layer (DPL) may include light-emitting elements (LDs) connected to the pixel circuits (PXCs) and light-receiving elements (PDs) connected to the sensor circuits (FXCs).

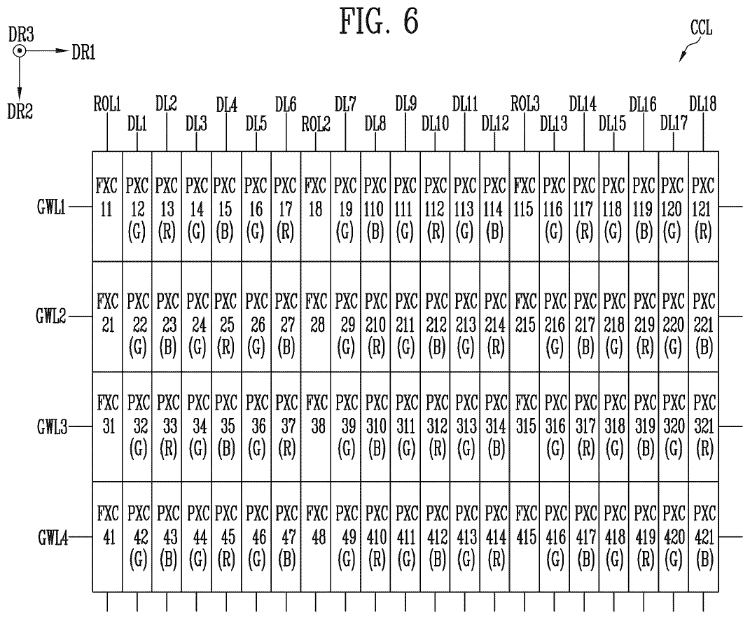

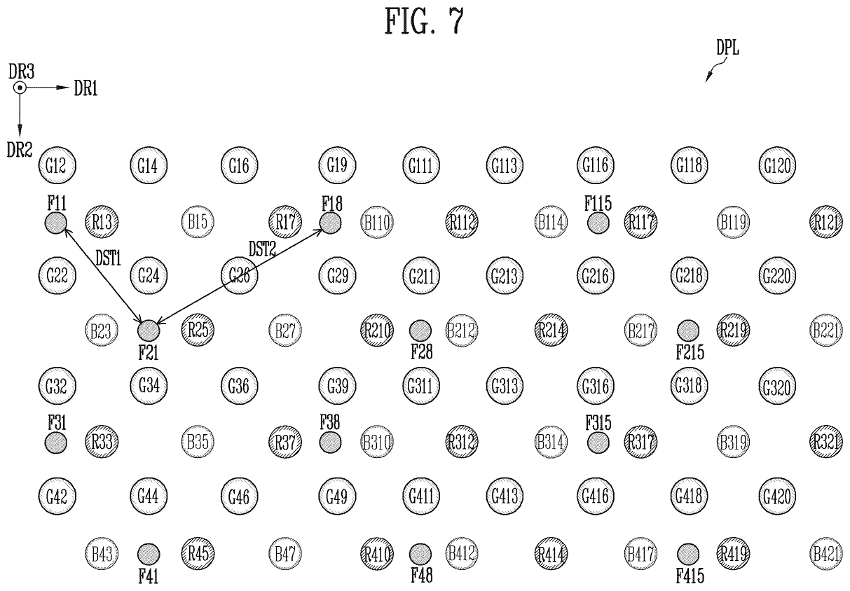

FIG. 6 is a plan view for illustrating a circuit layer according to an embodiment of the present disclosure. FIG. 7 is a plan view for illustrating an element layer according to an embodiment of the present disclosure.

FIGS. 6 and 7 are plan views for some areas of the display panel 10. Some areas of the display panel 10 are areas selected by the user's finger and may be sensing areas.

Referring to FIG. 6, the circuit layer (CCL) may include pixel circuits (PXC12, PXC13, PXC14, PXC15, PXC16, PXC17, PXC19, PXC110, PXC111, PXC112, PXC113, PXC114, PXC116, PXC117, PXC118, PXC119, PXC120, PXC121, PXC22, PXC23, PXC24, PXC25, PXC26, PXC27, PXC29, PXC210, PXC211, PXC212, PXC213, PXC214, PXC216, PXC217,PXC218, PXC219, PXC220, PXC221, PXC32, PXC33, PXC34, PXC35, PXC36, PXC37, PXC39, PXC310, PXC311, PXC312, PXC313, PXC314, PXC316, PXC317, PXC318, PXC319, PXC320,PXC321, PXC42, PXC43, PXC44, PXC45, PXC46, PXC47, PXC49, PXC410, PXC411, PXC412, PXC413, PXC414, PXC416, PXC417, PXC418, PXC419, PXC420, PXC421) and sensor circuits (FXC11, FXC18, FXC115, FXC21, FXC28, FXC215, FXC31, FXC38, FXC315, FXC41, FXC48, FXC415).

The pixel circuits (PXC12˜PXC421) may be connected to the light-emitting elements (LD) emitting light of the first color (R), the second color (G), or the third color (B). The first color (R), the second color (G), and the third color (B) may be different colors. For example, the first color (R) may be one of red, green, and blue, the second color (G) may be one of red, green, and blue which is not the first color (R), and the third color (B) may be any color other than the first color (R) and the second color (G) among red, green, and blue. In addition, magenta, cyan, and yellow may be used instead of red, green, and blue as the first to third colors (R, G, and B).

The sensor circuits and pixel circuits arranged in the first direction (DR1) may be connected to the same first scan line (GWL1, GWL2, GWL3, or GWL4). The sensor circuits arranged in the second direction (DR2) may be connected to the same readout line (ROLI, ROL2, or ROL3). The pixel circuits arranged in the second direction (DR2) may be connected to the same data line (DL1, DL2, DL3, DL4, DL5, DL6, DL7, DL8, DL9, DL10, DL11, DL12, DL13, DL14, DL15, DL16, DL17, or DL18).

Referring to FIG. 7, the element layer (DPL) may include light-emitting elements of the first color (R) (R13, R17, R112, R117, R121, R25, R210, R214, R219, R33, R37, R312, R317, R321, R45, R410, R414, R419), light-emitting elements of the second color (G) (G12, G14, G16, G19, G111, G113, G116, G118, G120, G22, G24, G26, G29, G211, G213, G216, G218, G220, G32, G34, G36, G39, G311, G313, G316, G318, G320, G42, G44, G46, G49, G411, G413, G416, G418, G420), and light-emitting elements of the third color (B) (B15, B110, B114, B119, B23, B27, B212, B217, B221, B35, B310, B314, B319, B43, B47, B412, B417, B421).

The light-emitting elements of the first color (R) (R13, R17, R112, R117, R121, R25, R210, R214, R219, R33, R37, R312, R317, R321, R45, R410, R414, R419) may be connected to the pixel circuits (PXC13, PXC17, PXC112, PXC117, PXC121, PXC25, PXC210, PXC214, PXC219, PXC33, PXC37, PXC312, PXC317, PXC321, PXC45, PXC410, PXC414, PXC419), respectively.

The light-emitting elements of the second color (G) (G12, G14, G16, G19, G111, G113, G116, G118, G120, G22, G24, G26, G29, G211, G213, G216, G218, G220, G32, G34, G36, G39, G311, G313, G316, G318, G320, G42, G44, G46, G49, G411, G413, G416, G418, G420) may be connected to the pixel circuits (PXC12, PXC14, PXC16, PXC19, PXC111, PXC113, PXC116, PXC118, PXC120, PXC22, PXC24, PXC26, PXC29, PXC211, PXC213, PXC216, PXC218, PXC220, PXC32, PXC34, PXC36, PXC39, PXC311, PXC313, PXC316, PXC318, PXC320, PXC42, PXC44, PXC46, PXC49, PXC411, PXC413, PXC416, PXC418, PXC420), respectively.

The light-emitting elements of the third color (B) (B15, B110, B114, B119, B23, B27, B212, B217, B221, B35, B310, B314, B319, B43, B47, B412, B417, B421) may be connected to the pixel circuits (PXC15, PXC110, PXC114, PXC119, PXC23, PXC27, PXC212, PXC217, PXC221, PXC35, PXC310, PXC314, PXC319, PXC43, PXC47, PXC412, PXC417, PXC421), respectively.

Further, the element layer (DPL) may include light-receiving elements (F11, F18, F115, F21, F28, F215, F31, F38, F315, F41, F48, F415). The light-receiving elements (F11, F18, F115,

F21, F28, F215, F31, F38, F315, F41, F48, F415) may be connected to the sensor circuits (FXC11, FXC18, FXC115, FXC21, FXC28, FXC215, FXC31, FXC38, FXC315, FXC41, FXC48, FXC415), respectively.

In the drawings below, the light-emitting elements (LD) of the display panel 10 are arranged in a diamond pixel (DIAMOND PIXEL™) or pentile (PENTILE™) structure as an example (see FIGS. 7, 8, 13, 14, and 15). In the pentile structure, the pixel of the first color (R) and the pixel of the second color (G) form a pair to form a group of pixels, and the pixel of the third color (B) and the pixel of the second color (G) form a pair to form a group of pixels. Here, the first color (R) may be red, the second color (G) may be green, and the third color (B) may be blue. The resolution of the pixel groups of the display panel 10 may be defined as PPI (pixel per inch). The resolution of the light-receiving elements (PDs) of the display panel 10 may be defined as DPI (dot per inch).

In order to generate valid sensing information, the minimum resolution of the light-receiving elements (PDs) may be 250 DPI (dot per inch). To achieve 426 PPI while maintaining the 250 DPI level, it is required to place one sensor circuit (FXC) for every two pixel groups (i.e., four pixel circuits (PXCs)). On the other hand, in order to achieve 496 PPI while maintaining the 250 DPI level, it is required to place one sensor circuit (FXC) for every four pixel groups (i.e., eight pixel circuits (PXCs)). In these cases, since planar spacing between the light-receiving elements (PDs) is constant, sensing information of uniform quality may be generated.

On the other hand, in order to achieve 450 PPI while maintaining the 250 DPI level, it is required to place one sensor circuit (FXC) for every three pixel groups (i.e., six pixel circuits (PXCs)) (see FIG. 6). At this time, it can be seen that for any one light-receiving element F21, the spacing between light-receiving elements (F11 and F21) (DST1) and the spacing between light-receiving elements (F18 and F21) (DST2) are different (see FIG. 7). In other words, an asymmetry of sensing information may occur for the first direction (DR1). In such cases, it is difficult to generate sensing information of uniform quality.

The light-emitting elements (G12˜G420) of the second color (G) connected to the same first scan line (GWL1, GWL2, GWL3, or GWL4) may be arranged in the first direction (DR1). The light-emitting elements (R13˜R419) of the first color (R) and the light-emitting elements (B15˜B421) of the third color (B) connected to the same first scan line (GWL1, GWL2, GWL3, or GWL4) may be arranged alternately in the first direction (DR1). At this time, the light-receiving elements (F11˜F415) may be located between the light-emitting element of the first color (R) and the light-emitting element of the third color (B) with respect to the first direction (DR1). In addition, the light-receiving elements (F11˜F415) may be located between the light-emitting elements of the second color (G) with respect to the second direction (DR2).

If the light-receiving element (F21) had been located at the position of the light-emitting element (R25), the planar spacings (DST1, DST2, . . . ) between the light-receiving element (F21) and the light-receiving elements (F11, F18, F31, F38) would have been constant. However, since the light-receiving element (F21) and the light-emitting element (R25) are located on substantially the same plane, the element layer (DPL), their positions on the plane cannot overlap.

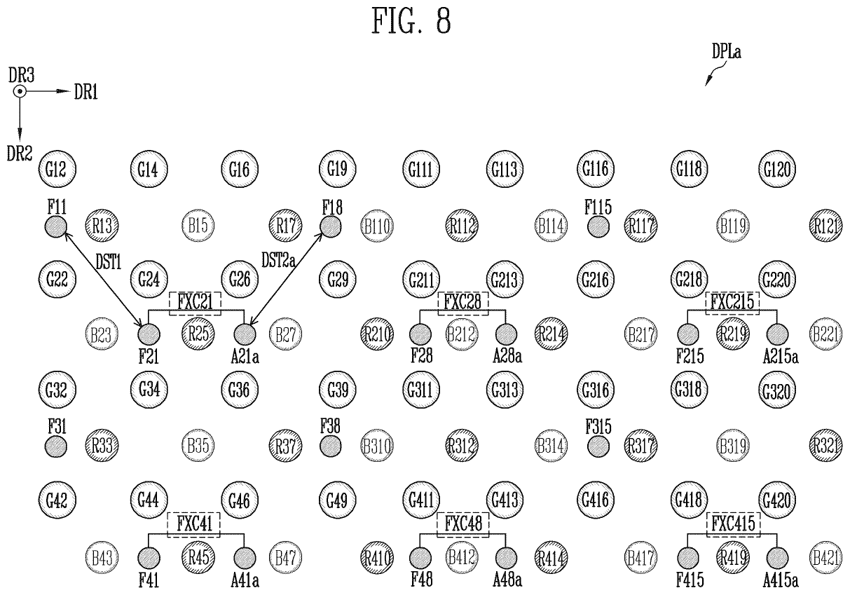

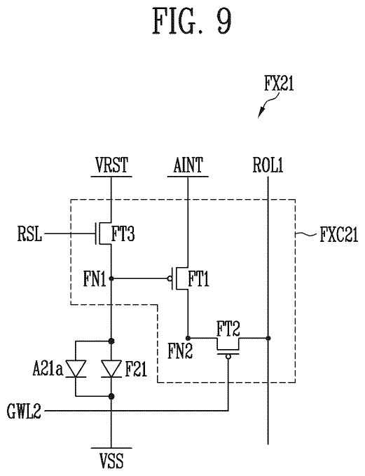

FIG. 8 is a plan view for illustrating an element layer according to another embodiment of the present disclosure. FIG. 9 is a drawing for illustrating an optical sensor including an auxiliary light-receiving element according to an embodiment of the present disclosure of FIG. 8.

Referring to FIGS. 8 and 9, based on the element layer (DPL) of FIG. 7, an element layer (DPLa) may further include auxiliary light-receiving elements (A21a, A28a, A215a, A41a, A48a, A415a).

For example, the sensor circuit (FXC21) may be connected to the light-receiving element (F21) and the auxiliary light-receiving element (A21a). Referring to FIG. 9, the optical sensor (FX21) may include the sensor circuit (FXC21), the light-receiving element (F21), and the auxiliary light-receiving element (A21a). Any description overlapping with that regarding the optical sensor (FX) of FIG. 3 is omitted. The light-receiving element (F21) and the auxiliary light-receiving element (A21a) may be connected in parallel. An anode electrode of the auxiliary light-receiving element (A21a) may be connected to a first node (FN1), and a cathode electrode of the auxiliary light-receiving element (A21a) may be connected to a second power line to which a second power supply voltage (VSS) is applied.

Similarly, the sensor circuit (FXC28) may be connected to the light-receiving element (F28) and the auxiliary light-receiving element (A28a). The sensor circuit (FXC215) may be connected to the light-receiving element (F215) and the auxiliary light-receiving element (A215a). The sensor circuit (FXC41) may be connected to the light-receiving element (F41) and the auxiliary light-receiving element (A41a). The sensor circuit (FXC48) may be connected to the light-receiving element (F48) and the auxiliary light-receiving element (A48a). The sensor circuit (FXC415) may be connected to the light-receiving element (F415) and an auxiliary light-receiving element (A415a).

The planar distance (DST1) of the light-receiving element (F11) and the light-receiving element (F21) may be substantially the same as a planar distance (DST2a) of the light-receiving element (F18) and the auxiliary light-receiving element (A21a). The sensor circuit (FXC11) and the sensor circuit (FXC18) may be commonly connected to the first scan line (GWL1). The first scan line (GWL2) connected to the sensor circuit (FXC21) may be the next scan line of the first scan line (GWL1).

In addition, the planar distance of the light-receiving element (F31) and the light-receiving element (F21) may be substantially the same as the plane distance of the light-receiving element (F38) and auxiliary light-receiving element (A21a). The first scan line (GWL3), to which the sensor circuit (FXC31) and the sensor circuit (FXC38) are commonly connected, may be the next scan line of the first scan line (GWL2).

When using the element layer (DPLa) of the present embodiment, the display device (DD) may generate symmetrical sensing information with respect to the first direction (DR1). Therefore, the display device (DD) may generate sensing information of uniform quality.

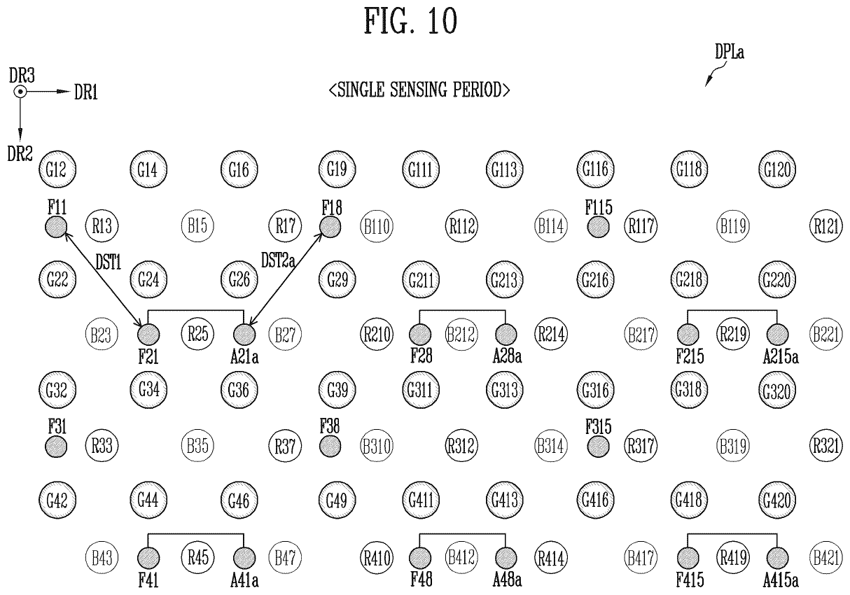

FIG. 10 is a drawing for illustrating a sensing method of the element layer of FIG. 8.

Hereinafter, the light-receiving elements (F11˜F415) and the auxiliary light-receiving elements (A21a˜A415a) are assumed to be elements which receive light of the second color (G).

For sensing, at least some of the light-emitting elements (LDs) located in the selected arca (i.e., sensing arca) may emit light in a sensing pattern. During a sensing period, first light-emitting elements (R13˜R419) and third light-emitting elements (B15˜B421) in the sensing area may be in a non-light-emitting state, and second light-emitting elements (G12˜G420) in the sensing area may be in a light-emitting state.

The sensing information may include sensing information (e.g., received brightness information) for the positions of the light-receiving elements (F11˜A415a). For example, the sensing information may include first sensing information for the position of the light-receiving element (F11), second sensing information for the position of the light-receiving element (F18), third sensing information for the position of the light-receiving element (F21), and fourth sensing information for the position of the auxiliary light-receiving element (A21a).

The first sensing information may correspond to the level of a first sensing signal output from the sensor circuit (FXC11). The second sensing information may correspond to the level of a second sensing signal output from the sensor circuit (FXC18).

On the other hand, the third sensing information may correspond to the half level of a third sensing signal output from the sensor circuit (FXC21). The fourth sensing information may correspond to the half level of the third sensing signal. For example, if the third sensing signal output from the sensor circuit (FXC21) to the readout line (ROL1) is X μA (microampere), the half level of the third sensing signal may be X/2 μA. In other words, in the embodiment of FIG. 10, the third sensing information and the fourth sensing information may be the same.

According to the embodiment of FIG. 10, sensing information may be generated for the entire sensing area for every one frame period (c.g., sensing period). According to the present embodiment, sensing information of uniform quality may be generated in a short time.

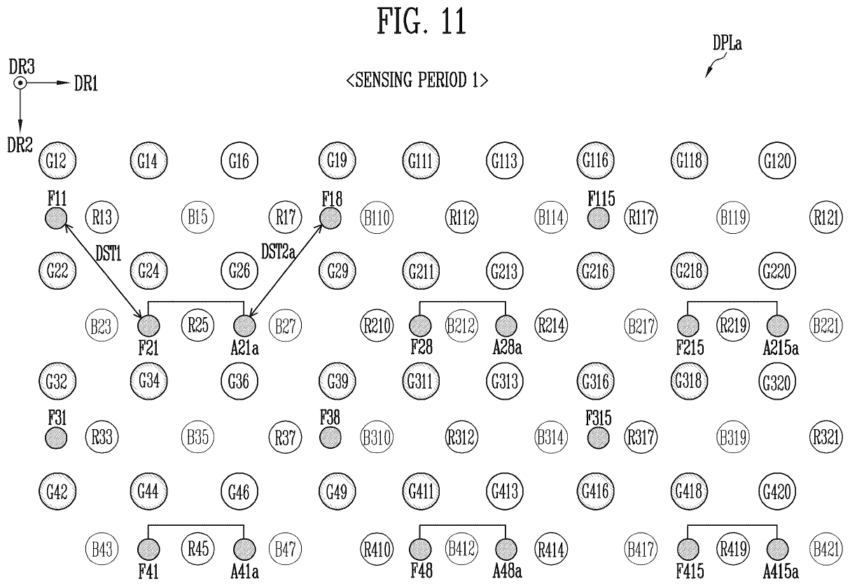

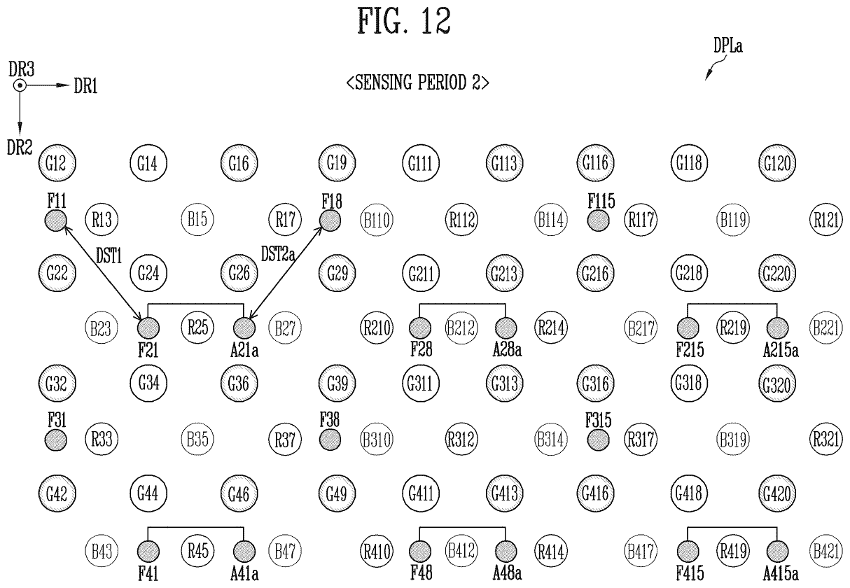

FIGS. 11 and 12 are diagrams for illustrating different sensing methods of the element layer of FIG. 8.

For sensing, at least some of the light-emitting elements (LDs) located in the selected area (i.e., sensing area) may emit light in the sensing pattern.

Refer to FIG. 11, during a first sensing period, the first light-emitting elements (R13˜R419) and the third light-emitting elements (B15˜B421) in the sensing area may be in the non-light-emitting state. During the first sensing period, the second light-emitting elements (G12, G19, G116, G22, G29, G216, G32, G39, G316, G42, G49, G416) adjacent to the light-receiving elements (F11, F18, F115, F31, F38, F315) of the optical sensors which include no auxiliary light-receiving element may be in the light-emitting state. During the first sensing period, the second light-emitting elements (G14, G111, G118, G24, G211, G218, G34, G311, G318, G44, G411, G418) adjacent to the light-receiving elements (F21, F28, F215, F41, F48, F415) of the optical sensors including the auxiliary light-receiving elements may be in the light-emitting state. During the first sensing period, the second light-emitting elements (G16, G113, G120, G26, G213, G220, G36, G313, G320, G46, G413, G420) adjacent to the auxiliary light-receiving elements (A21a, A28a, A215a, A41a, A48a, A415a) of the optical sensors including the auxiliary light-receiving elements may be in the non-light-emitting state. The term “adjacent” herein may refer to being adjacent in the second direction (DR2).

Referring to FIG. 12, during a second sensing period, the first light-emitting elements (R13˜R419) and the third light-emitting elements (B15˜B421) in the sensing area may be in the non-light-emitting state. During the second sensing period, the second light-emitting elements (G12, G19, G116, G22, G29, G216, G32, G39, G316, G42, G49, G416) adjacent to the light-receiving elements (F11, F18, F115, F31, F38, F315) of the optical sensors which includes no auxiliary light-receiving element may be in the light-emitting state. During the second sensing period, the second light-emitting elements (G14, G111, G118, G24, G211, G218, G34, G311, G318, G44, G411, G418) adjacent to the light-receiving elements (F21, F28, F215, F41, F48, F415) of the optical sensors including the auxiliary light-receiving elements may be in the non-light-emitting state. During the second sensing period, the second light-emitting elements (G16, G113, G120, G26, G213, G220, G36, G313, G320, G46, G413, G420) adjacent to the auxiliary light-receiving elements (A21a, A28a, A215a, A41a, A48a, A415a) of the optical sensors including the auxiliary light-receiving elements may be in the light-emitting state.

For example, the sensing information may include first sensing information for the position of the light-receiving element (F11), second sensing information for the position of the light-receiving element (F18), third sensing information for the position of the light-receiving element (F21), and fourth sensing information for the position of the auxiliary light-receiving element (A21a).

The first sensing information may correspond to an average level of the first sensing signal output during the first sensing period and the first sensing signal output during the second sensing period in the sensor circuit (FXC11). The second sensing information may correspond to an average level of the second sensing signal output during the first sensing period and the second sensing signal output during the second sensing period in the sensor circuit (FXC18).

The third sensing information may correspond to the level of the third sensing signal output during the first sensing period in the sensor circuit (FXC21). The fourth sensing information may correspond to the level of the third sensing signal output during the second sensing period in the sensor circuit (FXC21).

According to the embodiments of FIGS. 11 and 12, sensing information may be generated for the entire sensing area for each of the two frame periods (e.g., the first sensing period and the second sensing period). At this time, independent sensing signals may be acquired for each of the light-receiving elements and auxiliary light-receiving elements connected to the same sensing circuit, so that more accurate sensing information may be generated than the embodiment of FIG. 10.

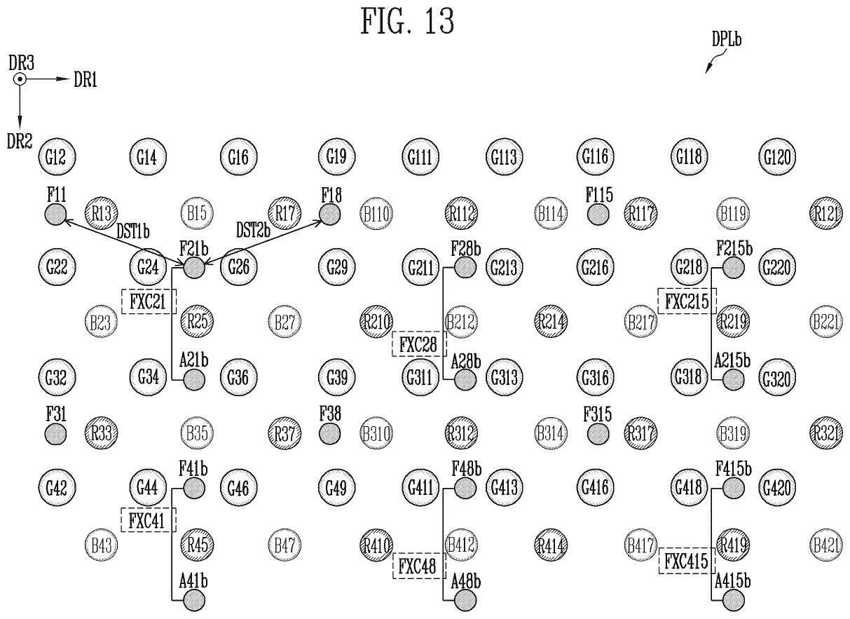

FIGS. 13 to 15 are diagrams for illustrating element layers according to other embodiments of the present disclosure.

Referring to FIG. 13, based on the element layer (DPL) of FIG. 7, an element layer (DPLb) may further include auxiliary light-receiving elements (A21b, A28b, A215b, A41b, A48b, A415b).

Further, based on the light-receiving elements (F21, F28, F215, F41, F48, F415) of the device layer (DPL) of FIG. 7, the positions of the light-receiving elements (F21b, F28b, F215b, F41b, F48b, F415b) may vary.

At this time, the light-receiving elements (F21b, F28b, F215b, F41b, F48b, F415b) may be located between the light-emitting element of the first color (R) and the light-emitting element of the third color (B) with respect to the second direction (DR2). In addition, the light-receiving elements (F21b, F28b, F215b, F41b, F48b, F415b) may be located between the light-emitting elements of the second color (G) with respect to the first direction (DR1).

Similarly, the auxiliary light-receiving elements (A21b, A28b, A215b, A41b, A48b, A415b) may be located between the light-emitting element of the first color (R) and the light-emitting element of the third color (B) with respect to the second direction (DR2). In addition, the auxiliary light-receiving elements (A21b, A28b, A215b, A41b, A48b, A415b) may be located between the light-emitting elements of the second color (G) with respect to the first direction (DR1).

The sensor circuit (FXC21) may be connected to the light-receiving element (F21b) and the auxiliary light-receiving element (A21b). The light-receiving element (F21b) and the auxiliary light-receiving element (A21b) may be connected in parallel (see the description of FIGS. 3 and 9). Similarly, the sensor circuit (FXC28) may be connected to the light-receiving element (F28b) and the auxiliary light-receiving element (A28b). The sensor circuit (FXC215) may be connected to the light-receiving element (F215b) and the auxiliary light-receiving element (A215b). The sensor circuit (FXC41) may be connected to the light-receiving element (F41b) and the auxiliary light-receiving element (A41b). The sensor circuit (FXC48) may be connected to the light-receiving element (F48b) and the auxiliary light-receiving element (A48b). The sensor circuit (FXC415) may be connected to the light-receiving element (F415b) and the auxiliary light-receiving element (A415b).

A planar distance (DST1b) between the light-receiving element (F11) and the light-receiving element (F21b) may be substantially the same as a planar distance (DST2b) between the light-receiving element (F18) and the light-receiving element (F21b). Further, the planar distance between the light-receiving element (F11) and the auxiliary light-receiving element (A21b) may be substantially the same as the planar distance of the light-receiving element (F18) and the auxiliary light-receiving element (A21b).

The sensor circuit (FXC11) and the sensor circuit (FXC18) may be commonly connected to the first scan line (GWL1). The first scan line (GWL2) connected to the sensor circuit (FXC21) may be the next scan line of the first scan line (GWL1).

The planar distance between the light-receiving element (F31) and the auxiliary light-receiving element (A21b) may be substantially the same as the planar distance of the light-receiving element (F38) and the auxiliary light-receiving element (A21b). The planar distance of the light-receiving element (F31) and the auxiliary light-receiving element (A21b) may be substantially the same as the planar distance (DST1b) between the light-receiving element (F11) and the light-receiving element (F21b). The planar distance between the light-receiving element (F38) and the auxiliary light-receiving element (A21b) may be substantially the same as the planar distance (DST2b) between the light-receiving element (F18) and light-receiving element (F21b).

The first scan line (GWL3) to which the sensor circuit (FXC31) and the sensor circuit (FXC38) are commonly connected may be the next scan line of the first scan line (GWL2).

When using the element layer (DPLb) of the present embodiment, the display device (DD) may generate symmetrical sensing information with respect to the first direction (DR1). Therefore, the display device (DD) may generate sensing information of uniform quality.

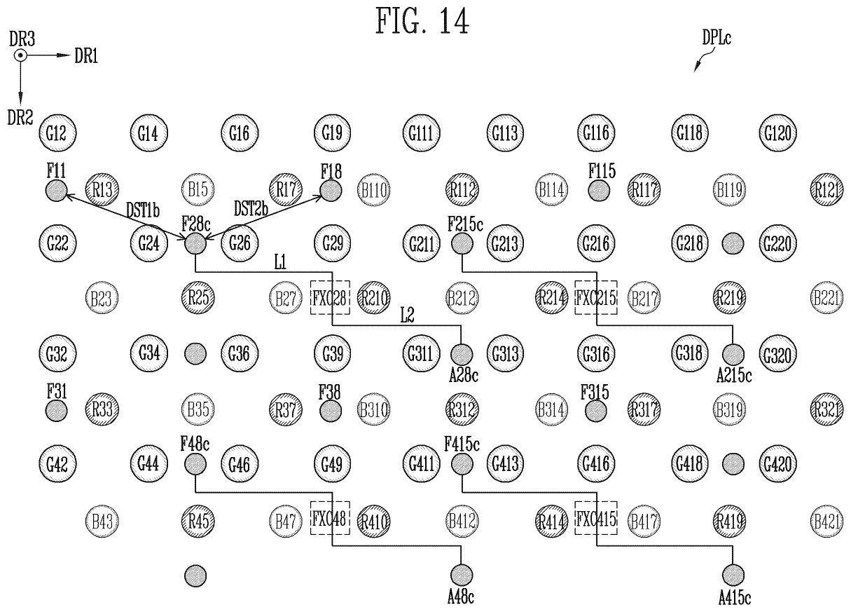

The positions of the light-receiving elements in an element layer (DPLc) of FIG. 14 may be substantially the same as the positions of the light-receiving elements in the element layer (DPLb) of FIG. 13. However, the sensor circuit to which the light-receiving elements in the element layer (DPLc) are connected may be different from the sensor circuit to which the light-receiving elements in the element layer (DPLb) are connected.

The sensor circuit (FXC28) may be connected to the light-receiving element (F28c) and the auxiliary light-receiving element (A28c). The light-receiving element (F28c) and the auxiliary light-receiving element (A28c) may be connected in parallel (see the description of FIGS. 3 and 9). Similarly, the sensor circuit (FXC215) may be connected to the light-receiving element (F215c) and the auxiliary light-receiving element (A215c). The sensor circuit (FXC48) may be connected to the light-receiving element (F48c) and the auxiliary light-receiving element (A48c). The sensor circuit (FXC415) may be connected to the light-receiving element (F415c) and the auxiliary light-receiving element (A415c).

For example, the length L1 of a conductor (or the length of a wire) connecting the light-receiving element (F28c) and the sensor circuit (FXC28) may be substantially the same as the length L2 of a conductor connecting the auxiliary light-receiving element (A28c) and the sensor circuit (FXC28). This configuration may be equally applied to other sensor circuits (FXC215, FXC48, FXC415). According to the present embodiment, it is possible to minimize the difference in sensing sensitivity between the light-receiving element and the auxiliary light-receiving element commonly connected to one sensor circuit.

Unlike FIG. 13, in the element layer (DPLc) of FIG. 14, the planar distance between the light-receiving element (F11) and the auxiliary light-receiving element (A21b) may be different from the planar distance between the light-receiving element (F18) and the auxiliary light-receiving element (A21b).

The planar distance between the light-receiving element (F38) and the auxiliary light-receiving element (A28c) may be substantially the same as the planar distance between the light-receiving element (F315) and the auxiliary light-receiving element (A28c). The light-receiving element (F18) may be located in the first direction (DR1) from the light-receiving element (F11), and the light-receiving element (F38) may be located in the second direction (DR2) from the light-receiving element (F18).

When using the element layer (DPLc) of the present embodiment, the display device (DD) may generate symmetrical sensing information with respect to the first direction (DR1). Therefore, the display device (DD) may generate sensing information of uniform quality.

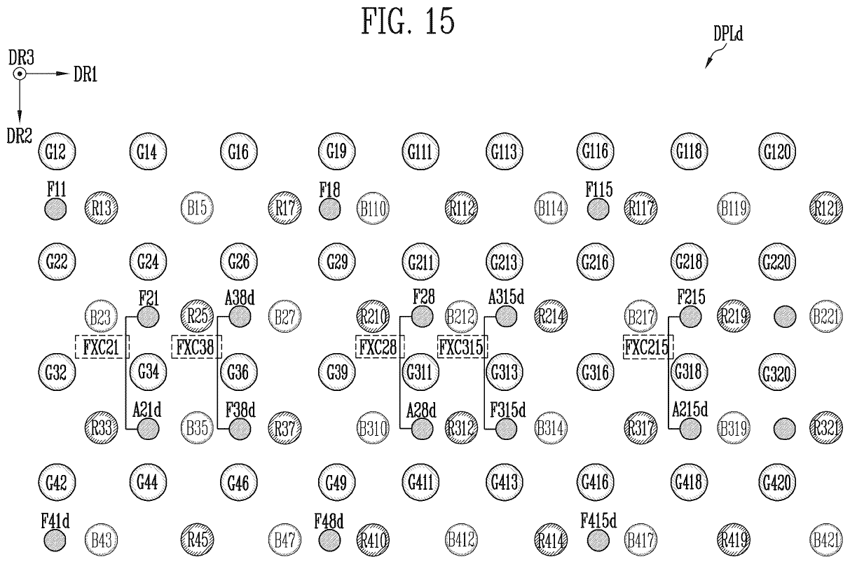

Referring to FIG. 15, based on the element layer (DPL) of FIG. 7, an element layer (DPLd) may further include auxiliary light-receiving elements (A38d, A315d, A21d, A28d, A215d). In addition, based on the light-receiving elements (F38, F315, F41, F48, F415) of the device layer (DPL) of FIG. 7, the positions of the light-receiving elements (F38d, F315d, F41d, F48d, F415d) may vary.

The sensor circuit (FXC21) may be connected to the light-receiving element (F21) and the auxiliary light-receiving element (A21d). The light-receiving element (F21) and the auxiliary light-receiving element (A21d) may be connected in parallel (see the description of FIGS. 3 and 9). Similarly, the sensor circuit (FXC38) may be connected to the light-receiving element (F38d) and the auxiliary light-receiving element (A38d). The sensor circuit (FXC28) may be connected to the light-receiving element (F28) and the auxiliary light-receiving element (A28d). The sensor circuit (FXC315) may be connected to the light-receiving element (F315d) and the auxiliary light-receiving element (A315d). The sensor circuit (FXC215) may be connected to the light-receiving element (F215) and the auxiliary light-receiving element (A215d).

The planar distance between the light-receiving element (F11) and the light-receiving element (F21) may be substantially the same as the planar distance between the light-receiving element (F18) and the auxiliary light-receiving element (A38d).

The light-receiving element (F18) may be located in the first direction (DR1) from the light-receiving element (F11). The auxiliary light-receiving element (A38d) may be located in the first direction (DR1) from the light-receiving element (F21). The light-receiving element (F38d) may be located in the first direction (DR1) from the auxiliary light-receiving element (A21d). The planar distance between the light-receiving element (F41d) and the auxiliary light-receiving element (A21d) may be substantially the same as the planar distance between the light-receiving element (F48d) and the light-receiving element (F38d).

The sensor circuit (FXC11) and the sensor circuit (FXC18) may be commonly connected to the first scan line (GWL1). The first scan line (GWL2) connected to the sensor circuit (FXC21) may be the next scan line of the first scan line (GWL1). The first scan line (GWL3) connected to the sensor circuit (FXC38) may be the next scan line of the first scan line (GWL2). The first scan line (GWL4) connected to the sensor circuit (FXC41) and the sensor circuit (FXC48) may be the next scan line of the first scan line (GWL3).

When using the element layer (DPLd) of the present embodiment, the display device (DD) may generate symmetrical sensing information with respect to the first direction (DR1). Therefore, the display device (DD) may generate sensing information of uniform quality.

Add Statement Regarding the Phrase “Substantially the Same” Defining Tolerances and Ranges of Distance and/or Length that Would be Substantially the Same

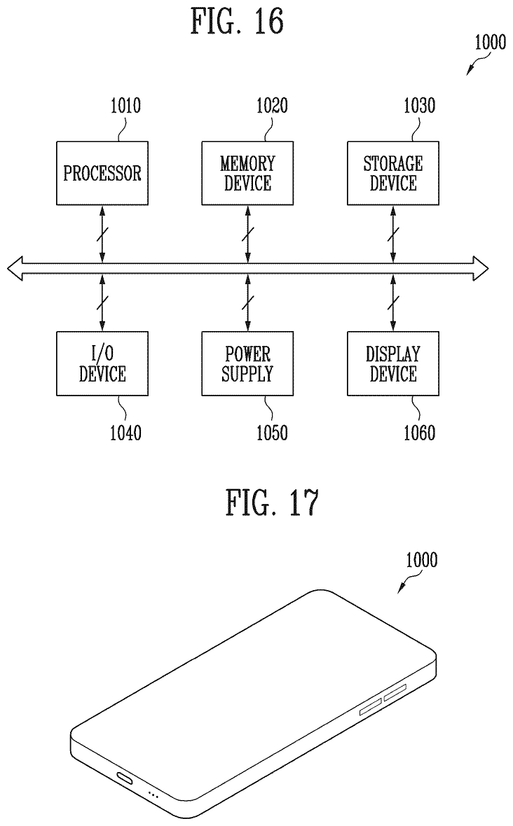

FIG. 16 is a block diagram illustrating an electronic device according to embodiments of the present disclosure. FIG. 17 is a drawing illustrating an example of the electronic device of

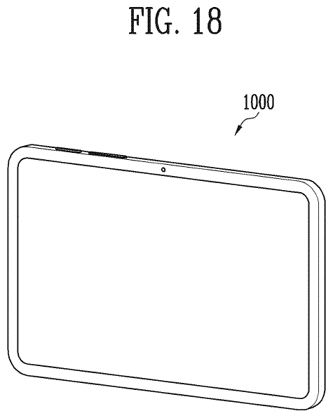

FIG. 16 implemented as a smartphone. FIG. 18 is a drawing illustrating an example of the electronic device of FIG. 16 implemented as a tablet PC.

Referring to FIGS. 16 to 18, an electronic device 1000 may include a processor 1010, a memory device 1020, a storage device 1030, an input/output (I/O) device 1040, a power supply 1050, and a display device 1060. Here, the display device 1060 may be the display device (DD) of FIG. 1. Further, the electronic device 1000 may further include multiple ports which may communicate with a video card, sound card, memory card, USB device, or the like or communicate with other systems. In one embodiment, as shown in FIG. 17, the electronic device 1000 may be implemented as a smartphone. In another embodiment, as shown in FIG. 18, the electronic device 1000 may be implemented as a tablet PC. However, these are exemplary and the electronic device 1000 is not limited thereto. For example, the electronic device 1000 may be implemented as a cellular phone, a video phone, a smart pad, a smart watch, a car navigation, a computer monitor, a laptop, a head-mounted display device, or the like.

The processor 1010 may perform particular calculations or tasks. According to embodiments, the processor 1010 may be a microprocessor, a central processing unit, an application processor, or the like. The processor 1010 may be connected to other components via an address bus, a control bus, and a data bus. According to embodiments, the processor 1010 may also be connected to an expansion bus, such as a Peripheral Component Interconnect (PCI) bus. The processor 1010 may be configured to provide input image data.

The memory device 1020 may store data necessary for operations of the electronic device 1000. For example, the memory device 1020 may include a nonvolatile memory device such as an crasable programmable read-only memory (EPROM) device, an electrically crasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or a volatile memory device such as a dynamic random access memory (DRAM) device, a static random access memory (SRAM) device, and a mobile DRAM device.

The storage device 1030 may include a solid state drive (SSD), a hard disk drive (HDD), a CD-ROM, etc.

The I/O device 1040 may include input means such as a keyboard, keypad, touchpad, touchscreen, mouse, etc., and output means such as a speaker, printer, etc. According to embodiments, the display device 1060 may be included in the I/O device 1040.

The power supply 1050 may supply power required for the operations of the electronic device 1000. For example, the power supply 1050 may be a power management integrated circuit (PMIC).

The display device 1060 may display an image corresponding to visual information of the electronic device 1000. Here, the display device 1060 may be, but the disclosure is not limited to, an organic light emitting display device or a quantum dot light emitting display device. The display device 1060 may be connected to other components via the buses or other communication links. The display device 1060 may be configured to display an image based on the input image data from the processor 1010.

The drawings referred to and the detailed description are merely illustrative of the present disclosure and are used only for the purpose of describing the present disclosure and not to limit the meaning or scope of the invention described in the appended claims. Therefore, those skilled in the art will understand that various variations and other equivalent embodiments are possible from this. Accordingly, the true technical protection scope of the present disclosure should be determined by the technical ideas of the appended claims.

What is claimed is:

1. A display device comprising:
a circuit layer comprising pixel circuits and sensor circuits; and
an element layer positioned on the circuit layer and comprising light-emitting elements connected to the pixel circuits and light-receiving elements connected to the sensor circuits,
wherein the light-receiving elements comprise a first light-receiving element, a second light-receiving element, a third light-receiving element, and a fourth light-receiving element,
wherein the sensor circuits comprise:
a first sensor circuit connected to the first light-receiving element;
a second sensor circuit connected to the second light-receiving element; and
a third sensor circuit connected to the third light-receiving element and the fourth light-receiving element, and
wherein a planar distance between the first light-receiving element and the third light-receiving element is substantially the same as a planar distance between the second light-receiving element and the fourth light-receiving element.

2. The display device according to claim 1, wherein the first sensor circuit and the second sensor circuit are commonly connected to a first scan line.

3. The display device according to claim 2, wherein a second scan line connected to the third sensor circuit is a next scan line of the first scan line.

4. The display device according to claim 1, wherein the light-receiving elements further comprise a fifth light-receiving element and a sixth light-receiving element,
wherein the sensor circuits comprise:
a fourth sensor circuit connected to the fifth light-receiving element; and
a fifth sensor circuit connected to the sixth light-receiving element, and
wherein a planar distance between the fifth light-receiving element and the third light-receiving element is substantially the same as a planar distance between the sixth light-receiving element and the fourth light-receiving element.

5. The display device according to claim 4, wherein the first sensor circuit and the second sensor circuit are commonly connected to a first scan line,
a second scan line connected to the third sensor circuit is a next scan line of the first scan line, and
a third scan line to which the fourth sensor circuit and the fifth sensor circuit are commonly connected is a next scan line of the second scan line.

6. The display device according to claim 1, wherein the light-emitting elements comprise first light-emitting elements configured to emit light of a first color, second light-emitting elements configured to emit light of a second color, and third light-emitting elements configured to emit light of a third color,
during a sensing period, the first light-emitting elements and the third light-emitting elements in a sensing area are in a non-light-emitting state, and the second light-emitting elements in the sensing area are in a light-emitting state,
sensing information comprises first sensing information for a position of the first light-receiving element, second sensing information for a position of the second light-receiving element, third sensing information for a position of the third light-receiving element, and fourth sensing information for a position of the fourth light-receiving element, and
the first sensing information corresponds to a level of a first sensing signal output from the first sensor circuit, the second sensing information corresponds to a level of a second sensing signal output from the second sensor circuit, the third sensing information corresponds to a half level of a third sensing signal output from the third sensor circuit, and the fourth sensing information corresponds to a half-level of the third sensing signal.

7. The display device according to claim 1, wherein the light-emitting elements comprise first light-emitting elements configured to emit light of a first color, second light-emitting elements configured to emit light of a second color, and third-emitting elements configured to emit light of a third color, and
during a first sensing period, the first light-emitting elements and the third light-emitting elements in a sensing area are in a non-light-emitting state, some of the second light-emitting elements adjacent to the first light-receiving element, the second light-receiving element, and the third light-receiving element are in a light-emitting state, and at least one of the second light-emitting elements adjacent to the fourth light-receiving element is in the non-light-emitting state.

8. The display device according to claim 7, wherein, during a second sensing period, the first light-emitting elements and the third light-emitting elements in the sensing area are in the non-light-emitting state, some of the second light-emitting elements adjacent to the first light-receiving element, the second light-receiving element, and the fourth light-receiving element are in the light-emitting state, and the at least one of the second light-emitting elements adjacent to the third light-receiving element is in the non-light-emitting state.

9. The display device according to claim 8, wherein sensing information comprises first sensing information for a position of the first light-receiving element, second sensing information for a position of the second light-receiving element, third sensing information for a position of the third light-receiving element, and fourth sensing information for a position of the fourth light-receiving element,
the first sensing information corresponds to an average level of a first sensing signal output during the first sensing period and a first sensing signal output during the second sensing period from the first sensor circuit,
the second sensing information corresponds to an average level of a second sensing signal output during the first sensing period and a second sensing signal output during the second sensing period from the second sensor circuit,
the third sensing information corresponds to a level of a third sensing signal output during the first sensing period from the third sensor circuit, and
the fourth sensing information corresponds to a level of a third sensing signal output during the second sensing period from the third sensor circuit.

10. A display device comprising:
a circuit layer comprising pixel circuits and sensor circuits; and
an element layer positioned on the circuit layer and comprising light-emitting elements connected to the pixel circuits and light-receiving elements connected to the sensor circuits,
wherein the light-receiving elements comprise a first light-receiving element, a second light-receiving element, a third light-receiving element, and a fourth light-receiving element,
wherein the sensor circuits comprise:
a first sensor circuit connected to the first light-receiving element;
a second sensor circuit connected to the second light-receiving element; and
a third sensor circuit connected to the third light-receiving element and the fourth light-receiving element, and
wherein a planar distance between the first light-receiving element and the third light-receiving element is substantially the same as a planar distance between the second light-receiving element and the third light-receiving element.

11. The display device according to claim 10, wherein a planar distance between the first light-receiving element and the fourth light-receiving element is substantially the same as a planar distance between the second light-receiving element and the fourth light-receiving element.

12. The display device according to claim 11, wherein the light-receiving elements further comprise a fifth light-receiving element and a sixth light-receiving element,
wherein the sensor circuits comprise:
a fourth sensor circuit connected to the fifth light-receiving element; and
a fifth sensor circuit connected to the sixth light-receiving element, and
wherein a planar distance between the fifth light-receiving element and the fourth light-receiving element is substantially the same as a planar distance of the sixth light-receiving element and the fourth light-receiving element.

13. The display device according to claim 12, wherein the first sensor circuit and the second sensor circuit are commonly connected to a first scan line,
a second scan line connected to the third sensor circuit is a next scan line of the first scan line, and
a third scan line to which the fourth sensor circuit and the fifth sensor circuit are commonly connected is a next scan line of the second scan line.

14. The display device according to claim 10, wherein a planar distance of the first light-receiving element and the fourth light-receiving element is different from a planar distance between the second light-receiving element and the fourth light-receiving element.

15. The display device according to claim 14, wherein a length of a conductor connecting the third light-receiving element and the third sensor circuit is substantially the same as a length of a conductor connecting the fourth light-receiving element and the third sensor circuit.

16. The display device according to claim 14, wherein the light-receiving elements further comprise a fifth light-receiving element and a sixth light-receiving element,
wherein the sensor circuits comprise:
a fourth sensor circuit connected to the fifth light-receiving element; and
a fifth sensor circuit connected to the sixth light-receiving element, and
wherein a planar distance between the fifth light-receiving element and the fourth light-receiving element is substantially the same as a planar distance between the sixth light-receiving element and the fourth light-receiving element.

17. The display device according to claim 16, wherein the second light-receiving element is located in a first direction from the first light-receiving element, and
the fifth light-receiving element is located in a second direction perpendicular to the first direction from the second light-receiving element.

18. An electronic device comprising:
a processor to provide input image data; and
a display device to display an image based on the input image data, the display device comprising:
a circuit layer comprising pixel circuits and sensor circuits; and
an element layer positioned on the circuit layer and comprising light-emitting elements connected to the pixel circuits and light-receiving elements connected to the sensor circuits,
wherein the light-receiving elements comprise a first light-receiving element, a second light-receiving element, a third light-receiving element, and a fourth light-receiving element,
wherein the sensor circuits comprise:
a first sensor circuit connected to the first light-receiving element;
a second sensor circuit connected to the second light-receiving element; and
a third sensor circuit connected to the third light-receiving element and the fourth light-receiving element, and
wherein a planar distance between the first light-receiving element and the third light-receiving element is substantially the same as a planar distance between the second light-receiving element and the fourth light-receiving element.

19. The electronic device according to claim 18, wherein the first sensor circuit and the second sensor circuit are commonly connected to a first scan line.

20. The electronic device according to claim 19, wherein a second scan line connected to the third sensor circuit is a next scan line of the first scan line.
